(19) United States
(12) Patent Application Publication
(10) Pub. No.: US 2026/0181861 A1
(43) Pub. Date: Jun. 25, 2026

(54) N-TYPE BULK SILICON MEMORY DEVICE USING FEEDBACK MECHANISM

(71) Applicant: KYONGGI UNIVERSITY INDUSTRY & ACADEMIA COOPERATION FOUNDATION, Suwon-si (KR)

(72) Inventors: Doo Hyeok LIM, Suwon-si (KR); Hak In KIM, Suwon-si (KR); Da On KIM, Suwon-si (KR)

(73) Assignee: KYONGGI UNIVERSITY INDUSTRY & ACADEMIA COOPERATION FOUNDATION, Suwon-si (KR)

(21) Appl. No.: 19/372,651

(22) Filed: Oct. 29, 2025

(30) Foreign Application Priority Data
Dec. 24, 2024 (KR) 10-2024-0195438

(51) Int. Cl. H10B 12/00

(52) U.S. Cl. CPC H10B 12/20

(57) ABSTRACT

The present disclosure relates to a memory device based on a bulk silicon substrate and to a technology for implementing stable memory operation without a capacitor. Specifically, the present disclosure relates to a technology for improving operational reliability of a memory device by preventing electrical interference and blocking leakage current by utilizing a positive feedback mechanism and a triple-well layer. The present disclosure relates to a technology for amplifying accumulation of electrons and holes through a positive feedback mechanism during memory operation, thereby improving switching speed and electrical reliability of the device. In addition, the present disclosure provides a memory device capable of operating stably even at low voltages by preventing electrical interference through the triple-well layer and blocking unnecessary current leakage.

### CROSS-REFERENCE TO RELATED APPLICATION

This application claims priority to Korean Patent Application No. 10-2024-0195438, filed on Dec. 24, 2024 in the Korean Intellectual Property Office, the disclosure of which is incorporated herein by reference.

### BACKGROUND OF THE DISCLOSURE

### Field of the Disclosure

The present disclosure relates to an n-type bulk silicon memory device using a feedback mechanism, and more particularly, to a technology capable of operating stably and efficiently as a one-transistor memory through a positive feedback mechanism without a capacitor by forming p-n junctions and a LOCOS structure that block leakage current in a bulk silicon substrate.

### Description of the Related Art

Semiconductor memory technology has evolved with the goal of high-speed data processing and large-capacity storage, and DRAM and SRAM have used 1T-1C structures and 6T structures, respectively, for high performance and reliability. Recently, one-transistor memory devices based on a positive feedback mechanism without capacitors have attracted attention for memory miniaturization and improved integration density. These devices have been developed on silicon-on-insulator (SOI) substrates, and research is being conducted to suppress leakage current and minimize interference between devices through the thin insulating layer of the SOI substrate. In particular, attempts are being made to block leakage paths through p-n junctions and implement stable memory characteristics by utilizing triple-well layers and Local Oxidation of Silicon (LOCOS) processes. Research is also being conducted to replace SOI substrates by forming p-n-p-n structures through complex epitaxial processes or multiple doping processes on bulk silicon substrates. These technological advances are moving toward reducing power consumption of memory devices, maximizing integration density, and simplifying manufacturing processes.

The biggest problem with conventional SOI substrate-based positive feedback mechanism memory devices is high manufacturing cost, making large-scale commercialization difficult due to the high cost of the substrate itself and complex manufacturing processes. In particular, SOI substrates have low thermal conductivity, which degrades the operating characteristics of memory devices in high-temperature environments, and there are limitations in maintaining electrical reliability. When triple-well layers are introduced or LOCOS processes are applied to solve leakage current problems, the processes become more complex and manufacturing costs increase, and when epitaxial technology is required, the process difficulty increases significantly. In addition, capacitors are essential in DRAM structures, which limit integration density and cause additional power consumption. The application of positive feedback mechanisms on bulk silicon substrates is economical compared to SOI substrates, but complex doping and structural design are required to block leakage current, resulting in low process efficiency and technical challenges remaining for commercialization. The need for memory devices with simple manufacturing processes that may secure both economy and reliability is increasing.

### RELATED ART DOCUMENT

### Patent Document

(Patent Document 1) Korean Patent No. 2499699 “Variable Logic-in-Memory Device Using Silicon Transistor”
(Patent Document 2) Korean Patent No. 2533714 “Single Layer Polysilicon Non-Volatile Memory Cell and Memory Thereof”

### SUMMARY OF THE DISCLOSURE

Therefore, the present disclosure has been made in view of the above problems, and it is an object of the present disclosure to solve problems of device characteristic degradation caused by high manufacturing costs and low thermal conductivity that occur in SOI substrates.

It is another object of the present disclosure to implement a memory device capable of effectively blocking leakage current while omitting complex epitaxial processes on a bulk silicon substrate.

It is still another object of the present disclosure to enable stable memory operation with one transistor without a capacitor by utilizing a positive feedback mechanism.

It is yet another object of the present disclosure to reduce interference between devices and improve reliability of memory devices through LOCOS processes and p-n junction isolation structures.

It is a further object of the present disclosure to develop an economical and efficient memory device by overcoming power consumption and integration density limitations of conventional DRAM structures.

In accordance with an aspect of the present disclosure, the above and other objects may be accomplished by providing an n-type bulk silicon memory device comprising: a triple-well layer formed on a bulk silicon substrate, the triple-well layer comprising an n-well formed on the bulk silicon substrate, a p-well formed within the n-well, and an n-well formed again within the p-well; a p+ drain formed within the n-well and an n+ source formed within the p-well; an insulating layer covering the p-well, the n-well, the p+ drain, and the n+ source; a metal wiring layer formed on the insulating layer and configured to transmit electrical signals; and a passivation layer configured to protect the metal wiring layer.

In accordance with another aspect of the present disclosure, the bulk silicon substrate may comprise a p-type or n-type semiconductor substrate.

In accordance with another aspect of the present disclosure, the metal wiring layer may be formed in a multilayer structure of copper (Cu) and aluminum (Al) to reduce resistance loss of electrical signals.

In accordance with another aspect of the present disclosure, the passivation layer may be formed of silicon oxynitride (SiON) to enhance electrical insulation properties.

In accordance with another aspect of the present disclosure, the insulating layer is formed to cover the bulk silicon substrate and the triple-well layer, and has a thickness between 5 nm and 10 nm.

In accordance with another aspect of the present disclosure, the triple-well layer may be formed between the n+ source and the p+ drain to provide electrical isolation between an active region and an inactive region of the bulk silicon substrate.

In accordance with another aspect of the present disclosure, the triple-well layer comprising the n-well, the p-well, and the n-well formed again may include a p-n-p-n junction to eliminate leakage current paths.

In accordance with another aspect of the present disclosure, the metal wiring layer may be formed in a multilayer structure with an insulating layer inserted between each layer.

In accordance with another aspect of the present disclosure, there is provided a method of manufacturing an n-type bulk silicon memory device, the method comprising: forming a triple-well layer on a bulk silicon substrate, the triple-well layer comprising an n-well, a p-well, and an n-well formed again; forming a p+ drain within the n-well and forming an n+ source within the p-well; forming an insulating layer covering the triple-well layer; forming a metal wiring layer on the insulating layer; and forming a passivation layer to protect the metal wiring layer.

In accordance with another aspect of the present disclosure, forming the triple-well layer may comprise injecting donor ions and acceptor ions into the bulk silicon substrate to generate the n-well, the p-well, and the n-well formed again.

In accordance with another aspect of the present disclosure, forming the insulating layer may comprise applying a thermal oxidation process to a surface of the bulk silicon substrate to form a silicon oxide layer (SiO₂).

In accordance with another aspect of the present disclosure, forming the metal wiring layer may comprise depositing a metal thin film comprising copper (Cu) or aluminum (Al), and forming wiring configured to transmit electrical signals through lithography and etching processes.

In accordance with another aspect of the present disclosure, the p+ drain may be formed through acceptor ion implantation.

In accordance with another aspect of the present disclosure, the insulating layer may be formed through a thermal oxidation process to prevent electrical interference that may occur on the bulk silicon substrate.

In accordance with another aspect of the present disclosure, the passivation layer may be formed through a plasma deposition process.

In accordance with another aspect of the present disclosure, the triple-well layer may be formed inside the active region formed by applying a Local Oxidation of Silicon (LOCOS) process to eliminate leakage current on a surface of the bulk silicon substrate.

In accordance with another aspect of the present disclosure, the triple-well layer may be formed through a high-concentration ion implantation process to prevent electrical interference between the p-well and the n-well formed on the bulk silicon substrate.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a structure of an n-type bulk silicon memory device in which leakage current is blocked through p-n junction isolation.

FIG. 2 is a structure of an n-type bulk silicon memory device in which leakage current is blocked through LOCOS isolation.

FIG. 3 is a structure of an n-type bulk silicon memory device in which leakage current is blocked through p-n junction isolation when utilizing an n-type silicon substrate.

FIG. 4 is a structure of an n-type bulk silicon memory device proposed in the present disclosure.

FIG. 5 is a diagram illustrating a memory operation principle of the n-type bulk silicon memory device of the present disclosure.

FIGS. 6A and 6B are embodiments of memory operation of the n-type bulk silicon memory device of the present disclosure.

### DETAILED DESCRIPTION OF THE DISCLOSURE

Specific structural or functional descriptions of embodiments according to the concept of the present invention disclosed herein are merely illustrated for the purpose of describing the embodiments according to the concept of the present invention, and the embodiments according to the concept of the present invention may be implemented in various forms and are not limited to the embodiments described herein.

Since the embodiments according to the concept of the present invention may be subject to various modifications and may take various forms, the embodiments will be illustrated in the drawings and described in detail in the specification. However, this is not intended to limit the embodiments according to the concept of the present invention to specific disclosed forms, but rather to include modifications, equivalents, or alternatives that fall within the spirit and scope of the present invention.

Terms such as “first” or “second” may be used to describe various elements, but such elements should not be limited by the terms. The terms are used only to distinguish one element from another, and for example, without departing from the scope of the present invention, a first element may be designated as a second element, and similarly, a second element may be designated as a first element.

When an element is referred to as being “connected” or “coupled” to another element, it should be understood that the element may be directly connected or coupled to the other element, or intervening elements may be present. In contrast, when an element is referred to as being “directly connected” or “directly coupled” to another element, it should be understood that no intervening elements are present. Expressions describing relationships between elements, such as “between,” “directly between,” or “adjacent to,” should be interpreted in the same manner.

The terminology used in this specification is for the purpose of describing particular embodiments only and is not intended to limit the present invention. Singular forms are intended to include plural forms unless the context clearly dictates otherwise. As used herein, the terms “comprise” and “have” specify the presence of stated features, integers, steps, operations, elements, parts, or combinations thereof, but do not preclude the presence or addition of one or more other features, integers, steps, operations, elements, parts, or combinations thereof.

Unless otherwise defined, all terms used herein, including technical and scientific terms, have the same meaning as commonly understood by one of ordinary skill in the art to which this invention belongs. Terms defined in generally used dictionaries should be interpreted as having meanings consistent with their usage in the relevant technical context, and unless expressly defined in this specification, they should not be interpreted in an idealized or overly formal sense.

Hereinafter, embodiments will be described in detail with reference to the accompanying drawings. However, the scope of the patent application is not limited or restricted to such embodiments. The same reference numerals in the drawings denote the same elements.

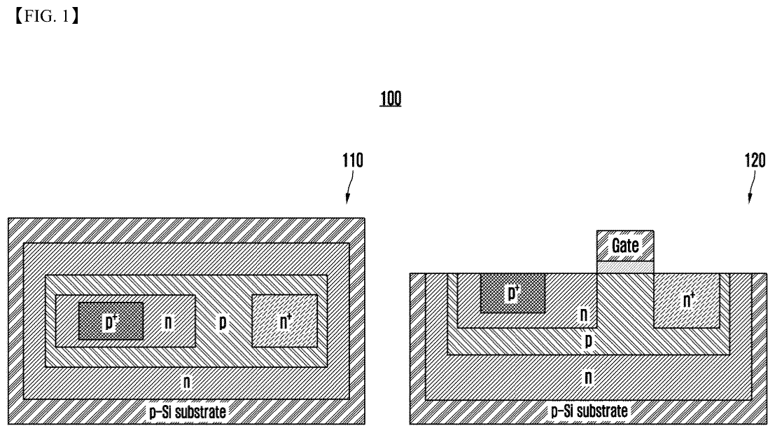

FIG. 1 is a structure of an n-type bulk silicon memory device in which leakage current is blocked through p-n junction isolation.

The structure of the n-type bulk silicon memory device 110 is characterized by forming a triple-well having a p-n-p-n structure in which a p-well and a p+ region are isolated from each other through an n-well in an active channel region of a bulk silicon substrate, thereby eliminating a leakage path through electrical isolation by p-n junction.

The n-type bulk silicon memory device 120 of FIG. 1 includes a triple-well layer comprising an n-well, a p-well, and an n-well formed again, based on a bulk silicon substrate (p-Si substrate). In addition, a p+ drain is formed within the n-well, and an n+ source is formed within the p-well. An insulating layer covering these structures is formed, and a metal wiring layer configured to transmit electrical signals is formed on the insulating layer. Finally, a passivation layer configured to protect the metal wiring layer is formed.

The bulk silicon substrate may comprise a p-type or n-type semiconductor substrate. The metal wiring layer is formed in a multilayer structure of copper (Cu) and aluminum (Al) to reduce resistance loss of electrical signals. The passivation layer is formed of silicon oxynitride (SiON) to enhance electrical insulation properties. The insulating layer is formed to cover the bulk silicon substrate and the triple-well structure, and has a thickness between 5 nm and 10 nm.

The triple-well structure is formed between the n+ source and the p+ drain to provide electrical isolation between an active region and an inactive region of the bulk silicon substrate. The triple-well structure includes a p-n-p-n junction to eliminate leakage current paths. The metal wiring layer is formed in a multilayer structure, and an insulating layer is inserted between each layer.

Specifically, the bulk silicon substrate (p-Si substrate) comprises a p-type semiconductor and provides a basic structure of the memory device. The bulk silicon substrate has high thermal conductivity and ensures reduction of leakage current and a stable operating environment. The n-well is formed on the bulk silicon substrate and is generated through a donor ion implantation process (dose: 8×10¹² cm⁻², energy: 160 keV).

A p-well is formed within the n-well, and the p-well is formed through an acceptor ion implantation process (dose: 3×10¹³ cm⁻², energy: 130 keV). An n-well is formed again inside the p-well, and this n-well is formed through a donor ion implantation process (dose: 4×10¹³ cm⁻², energy: 60 keV). The triple-well layer formed through these processes includes a p-n-p-n junction, which provides electrical isolation to block leakage current and prevent electrical interference between devices.

A p+ drain is formed within the n-well, and the p+ drain is formed through an acceptor ion (dose: 1×10¹⁵ cm⁻², energy: 30 keV) implantation process. An n+ source is formed within the p-well, and the n+ source is formed through a donor ion (dose: 1×10¹⁵ cm⁻², energy: 30 keV) implantation process. These p+ drain and n+ source each form major electrical paths for operation of the memory device.

The exterior of the triple-well layer is covered with an insulating layer. The insulating layer comprises a silicon oxide layer (SiO₂) formed through a thermal oxidation process, and the thickness is maintained between 5 nm and 10 nm. The insulating layer protects the internal structure including the bulk silicon substrate and the triple-well layer from electrical interference and enhances stability of the device.

A metal wiring layer is formed on the insulating layer. The metal wiring layer includes a multilayer structure comprising copper (Cu) and aluminum (Al), and an insulating layer is inserted between each wiring layer to prevent electrical interference. The metal wiring layer is formed through lithography and etching processes and serves as a major pathway for transmitting electrical signals of the memory device.

A passivation layer is formed on the exterior of the metal wiring layer. The passivation layer comprises silicon oxynitride (SiON) formed through a plasma deposition process and protects the metal wiring layer from physical and chemical damage of the external environment. The passivation layer also serves to ensure long-term reliability of the device.

FIG. 1 shows that leakage current is effectively blocked through p-n junction isolation through the structure of the n-type bulk silicon memory device 100. The triple-well layer includes a p-n-p-n junction to prevent electrical interference and provide a stable memory operation environment. The metal wiring layer and the passivation layer minimize loss of electrical signals and maintain reliability of the device. The overall structure enables stable one-transistor memory operation based on a positive feedback mechanism without a capacitor.

A method of manufacturing an n-type bulk silicon memory device according to an embodiment begins with forming a triple-well layer comprising an n-well, a p-well, and an n-well formed again on a bulk silicon substrate. Next, a p+ drain is formed within the n-well, and an n+ source is formed within the p-well. Subsequently, an insulating layer covering the triple-well layer is formed, and a metal wiring layer is formed thereon. Finally, a passivation layer configured to protect the metal wiring layer is formed.

Forming the triple-well layer is accomplished by injecting donor ions and acceptor ions into the bulk silicon substrate to generate an n-well, a p-well, and an n-well formed again. Forming the insulating layer is accomplished by applying a thermal oxidation process to a surface of the bulk silicon substrate to form a silicon oxide layer (SiO₂). Forming the metal wiring layer proceeds by depositing a metal thin film comprising copper (Cu) or aluminum (Al) and then forming wiring configured to transmit electrical signals through lithography and etching processes.

The insulating layer is formed through a thermal oxidation process to prevent electrical interference that may occur on the bulk silicon substrate. The passivation layer is formed through a plasma deposition process. The triple-well layer may be formed inside the active region formed by applying a Local Oxidation of Silicon (LOCOS) process to eliminate leakage current on a surface of the bulk silicon substrate. In addition, the triple-well layer may be formed through a high-concentration ion implantation process to prevent electrical interference between the p-well and the n-well.

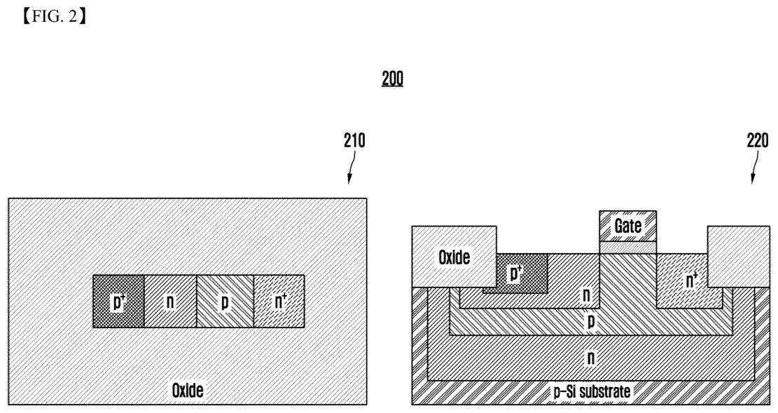

FIG. 2 is a structure 200 of an n-type bulk silicon memory device in which leakage current is blocked through LOCOS isolation.

In the present disclosure, as shown by reference numeral 210, regions other than the active channel in the bulk silicon substrate may eliminate leakage paths that may flow to the substrate surface by performing a LOCOS process.

Specifically, in the structure 210 of the n-type bulk silicon memory device, for regions other than the active channel region in the bulk silicon substrate, a leakage path generated toward the substrate surface may be eliminated through a Local Oxidation of Silicon (LOCOS) process.

The LOCOS process forms an oxide layer on the silicon surface to block paths through which leakage current may flow.

In the LOCOS process, oxidation of the silicon surface is induced to form an oxide layer. In this process, the oxide layer has electrically insulating properties and blocks charge movement. In addition, the oxide layer formed outside the active channel region prevents leakage of electrical signals and suppresses unnecessary current flow.

The oxide layer formed by the LOCOS process minimizes capacitive effects that may occur in surrounding areas where the memory device is located. Through this, the memory device maintains high operational stability and may ensure data integrity.

The present disclosure may completely eliminate leakage paths of the device physically and electrically by combining the triple-well structure and the LOCOS process. Due to this, power consumption is reduced and performance of the device may be significantly improved.

Referring to reference numeral 220, the n-type bulk silicon memory device 200 is based on a bulk silicon substrate (p-Si substrate) and includes a structure comprising a p-well, an n-well, a p+ drain, an n+ source, an oxide layer, and a gate.

The bulk silicon substrate (p-Si substrate) comprises a p-type semiconductor and provides a basic structure of the memory device.

The bulk silicon substrate (p-Si substrate) provides high thermal conductivity and supports a stable operating environment for the memory device. The n-well is formed on the bulk silicon substrate and is formed through a process of injecting donor ions (dose: 8×10¹² cm⁻², energy: 160 keV).

A p-well is formed within the n-well, and the p-well is formed through an acceptor ion (dose: 3×10¹³ cm 2, energy: 110 keV) implantation process. A p+ drain is formed inside the n-well, and the p+ drain is formed by injecting acceptor ions (dose: 1×10¹⁵ cm⁻², energy: 30 keV).

An n+ source is formed inside the p-well, and the n+ source is formed through a donor ion (dose: 1×10¹⁵ cm 2, energy: 30 keV) implantation process. The p+ drain and the n+ source each form major electrical paths of the memory device and enable reliable electrical signal transmission.

The Local Oxidation of Silicon (LOCOS) process forms an oxide silicon layer outside the p-well and n-well regions to eliminate leakage current paths. The LOCOS process forms an oxide layer in regions outside the active channel of the bulk silicon substrate to prevent electrical interference and effectively block interference between devices. The oxide silicon layer formed in the LOCOS process enhances stability of the bulk silicon substrate and ensures reliability of the memory device.

The gate is formed on the n-well and serves as a control electrode of the memory device. The gate adjusts electrical signals according to externally applied voltage and controls the electrical path between the p+ drain and the n+ source. The gate enables read, write, and hold operations of the memory device.

The p-well and the n-well provide a stable operating environment through electrical isolation, and the p-n junction performs an additional role of preventing electrical interference. This structure maximizes performance of the memory device by blocking leakage current and preventing interference between devices.

FIG. 2 enables operation of a stable n-type bulk silicon memory device 200 utilizing LOCOS isolation through these structural features.

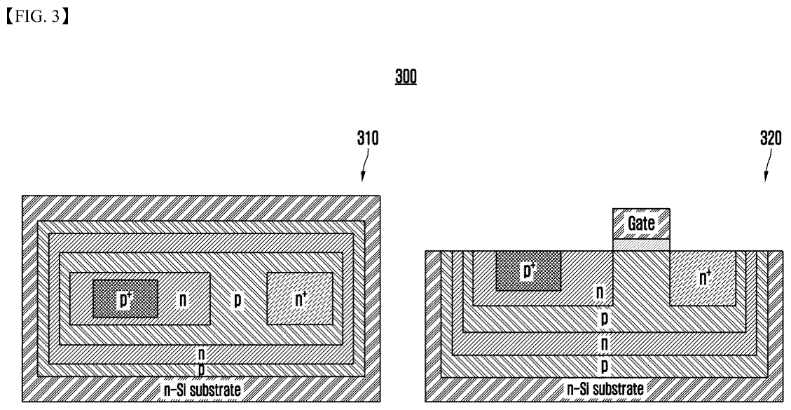

FIG. 3 is a structure of an n-type bulk silicon memory device in which leakage current is blocked through p-n junction isolation when utilizing an n-type silicon substrate.

The bulk silicon memory device of the present disclosure was fabricated with a p-type semiconductor substrate, and when the bulk silicon memory device is fabricated with an n-type silicon substrate, as shown in FIG. 3, a p-well is formed in the substrate, an n-well is formed within the p-well, and another p-well is formed within the n-well to form a triple-well.

When an n region is formed to surround the p+ drain so that the p-well and the p+ drain are not connected to each other, thereby forming a p-n-p-n structure within the triple-well, electrical isolation by p-n junction may be achieved.

The n-type bulk silicon memory device 300 is based on an n-type silicon substrate (n-Si substrate) and includes a structure comprising a p-well, an n region, a p+ drain, an n+ source, and a gate.

The n-type silicon substrate (n-Si substrate) comprises an n-type semiconductor and provides a foundation for the memory device. This substrate has high electrical conductivity and forms a stable electrical path and a basic structure for operation of the memory device.

The p-well is formed by injecting acceptor ions into an upper portion of the n-type silicon substrate.

The p-well provides electrical isolation and effectively prevents leakage current of the device through the difference in electrical characteristics from the n-type silicon substrate. An n-well is formed inside the p-well, and the n-well is formed by injecting donor ions. The n-well forms a p-n junction with the p-well, and this junction structure prevents electrical interference and ensures stable memory operation.

A p+ drain is formed inside the n-well. The p+ drain is formed by injecting acceptor ions.

The p+ drain serves to control current flow within the n-well and forms a major electrical path of the memory device. An n+ source is formed outside the n-well, and the n+ source is formed by injecting donor ions. The n+ source serves to receive external electrical signals and constitutes a core electrical path of the memory device together with the p+ drain.

The p-well and the n-well form a p-n junction to provide electrical isolation. This p-n junction structure effectively prevents leakage current and eliminates electrical interference between devices, thereby enabling stable operation of the memory device.

The p-n junction structure formed at the boundary between the p-well and the n-well enhances the role of preventing electrical interference and maximizes performance of the memory device. The gate is formed on the n-well and serves as a control electrode of the memory device.

The gate controls the electrical connection between the p+ drain and the n+ source by adjusting externally applied voltage. The gate enables read, write, and hold operations of the memory device, and these operations ensure stability and reliability of the device.

In the structure of FIG. 3, the n-type silicon substrate provides high electrical conductivity and forms a basic structure of the device. The p-n junction of the p-well and the n-well blocks leakage current and prevents electrical interference. The p+ drain and the n+ source each form major electrical paths of the memory device and enable stable electrical signal transmission.

The gate is responsible for controlling the memory device and adjusts the connection between the p+ drain and the n+ source based on external electrical signals.

The p-n junction isolation effectively blocks leakage current and provides high reliability and stability by preventing interference between devices. In addition, the gate that adjusts the electrical connection between the p+ drain and the n+ source controls the state of the memory device and ensures efficient and stable operation.

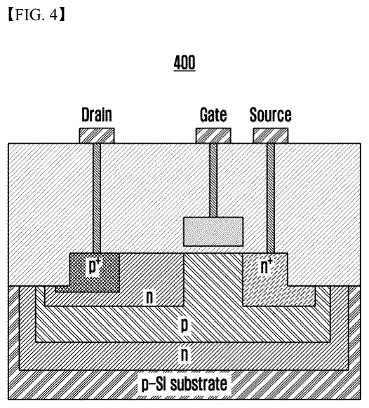

FIG. 4 is a structure of an n-type bulk silicon memory device proposed in the present disclosure.

As shown in FIG. 4, when a triple-well is formed in the bulk silicon substrate and the energy band of the channel region is formed in a p-n-p-n structure, a hysteresis phenomenon occurring within the device due to a positive feedback loop phenomenon may be utilized as a memory characteristic.

The n-type bulk silicon memory device 400 comprises a p-well, an n-well, a p+ drain, an n+ source, a gate, a drain electrode, and a source electrode formed on a bulk silicon substrate (p-Si substrate).

The bulk silicon substrate (p-Si substrate) comprises a p-type semiconductor and provides a basic structure of the memory device.

The bulk silicon substrate has high thermal conductivity and electrical stability and serves to enhance reliability of the device. The n-well is formed by injecting donor ions (dose: 8×10¹² cm⁻², energy: 160 keV) into the bulk silicon substrate. The n-well provides electrical isolation through junction with the p-well and enhances operational reliability of the device by blocking leakage current.

A p-well is formed inside the n-well, and the p-well is formed through a process of injecting acceptor ions (dose: 3×10¹³ cm⁻², energy: 60 keV). The n-well forms a p-n junction structure with the p-well, which plays an important role in preventing electrical interference between devices and stably maintaining electrical paths.

A p+ drain is formed inside the n-well, and the p+ drain is formed by injecting acceptor ions (dose: 1×10¹⁵ cm⁻², energy: 30 keV). The p+ drain provides a major electrical path for controlling current flow and performs a core function of the memory device.

An n+ source is formed inside the p-well, and the n+ source is formed by injecting donor ions (dose: 1×10¹⁵ cm⁻², energy: 30 keV). The n+ source serves to receive external electrical signals and constitutes an electrical connection of the memory device together with the p+ drain.

The p-well and the n-well form a p-n junction structure, which prevents electrical interference between devices and blocks leakage current to ensure stable operation. The p-n junction structure formed at the boundary between the p-well and the n-well further enhances electrical isolation and stability, thereby maximizing performance of the memory device.

The gate is formed on the n-well and serves as a control electrode of the memory device. The gate adjusts the electrical connection between the p+ drain and the n+ source according to externally applied voltage and enables read, write, and hold operations of the memory device.

In addition, the drain and source electrodes operate together with the gate and are connected to the p+ drain and the n+ source, respectively, to complete an electrical connection path with the outside.

FIG. 4 shows that the bulk silicon substrate provides high thermal conductivity and electrical stability and forms a basic structure of the device.

The p-n junction of the p-well and the n-well blocks leakage current and prevents electrical interference between devices. The p+ drain and the n+ source form major electrical paths of the memory device and enable stable and reliable electrical signal transmission. The gate adjusts the connection between the p+ drain and the n+ source based on external voltage and is responsible for controlling the device. The drain and source electrodes provide electrical connection with the outside to support operation of the memory device.

FIG. 4 shows that through this design, the n-type bulk silicon memory device may effectively block leakage current and provide stable operation and high reliability.

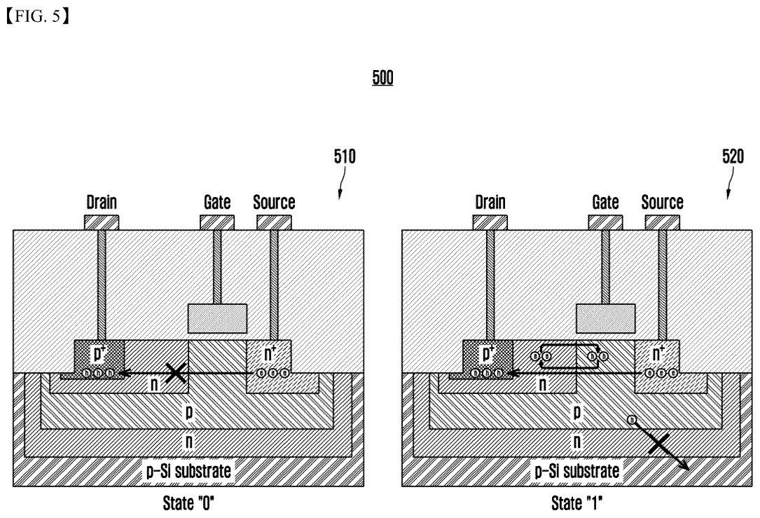

FIG. 5 is a diagram illustrating a memory operation principle of the n-type bulk silicon memory device of the present disclosure.

In the n-type bulk silicon memory device of the present disclosure, memory characteristics occur due to a feedback loop mechanism in which electrons and holes are accumulated or annihilated in potential wells, and since it has a triple-well structure, interference between devices does not occur.

It is based on a structure comprising the bulk silicon substrate (p-Si substrate), p-well, n-well, p+ drain, n+ source, and gate of FIG. 5.

The n-type bulk silicon memory device implements memory characteristics without a capacitor by utilizing a positive feedback mechanism and enables stable operation.

In the n-type bulk silicon memory device 500, current does not flow between the p+ drain and the n+ source in an initial state. The p-n junction of the p-well and the n-well provides electrical isolation, thereby blocking leakage current.

When voltage applied to the gate is absent or low, holes inside the p+ drain and electrons inside the n+ source do not move and remain in place.

This is because the p-n junction structure and the triple-well layer prevent electrical interference and block current flow. In this state, the memory device operates in a “storage state (OFF),” and flow of electrical signals does not occur.

When external voltage is applied to the gate, the memory device is activated, and an electric field generated by the gate induces an electrical connection between the p+ drain and the n+ source.

The positive feedback mechanism operates, and holes inside the p+ drain move to the p-well, accumulate, and eventually flow to the n+ source, while electrons inside the n+ source move to the n-well, accumulate, and eventually flow to the p+ drain. Due to this, current flows between the p+ drain and the n+ source, and the memory device switches to an “active state (ON).” The current flow is amplified by the influence of the electric field, and this amplification is further enhanced by the positive feedback mechanism.

The operation of the n-type bulk silicon memory device is maintained more stably by the triple-well layer. The triple-well layer comprising the n-well, the p-well, and the n-well formed again prevents electrical interference and induces the current flow of the device to be restricted to specific paths. The p-n junction structure between the p-well and the n-well blocks unnecessary current leakage, eliminates interference between devices, and ensures stable transmission of electrical signals.

The positive feedback mechanism induces amplification of current and enables the memory device to stably switch between “0” state and “1” state. In the “0” state, current does not flow, and in the “1” state, current flow is stably maintained. The positive feedback mechanism enhances electrical interaction between electrons generated at the p+ drain and electrons generated at the n+ source, thereby improving switching speed and stability of the memory device.

The bulk silicon substrate (p-Si substrate) provides a basic structure of the memory device and enhances reliability of the device through high thermal conductivity and electrical stability. The p-well and the n-well form a p-n junction structure to provide electrical isolation and prevent unnecessary movement of holes and electrons. In addition, electrons inside the n+ source and holes inside the p+ drain move through specific paths through an electric field induced by gate voltage, thereby enabling operation of the memory device.

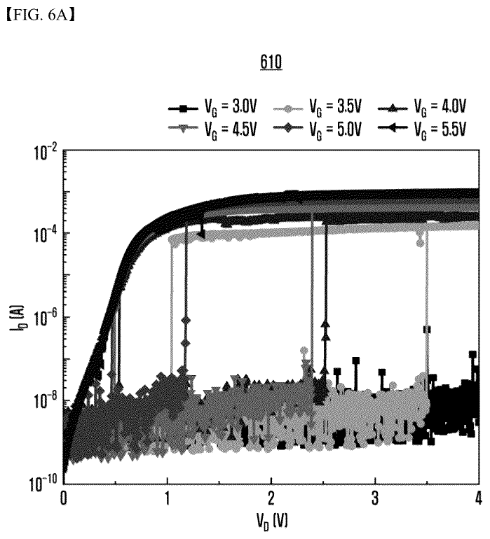

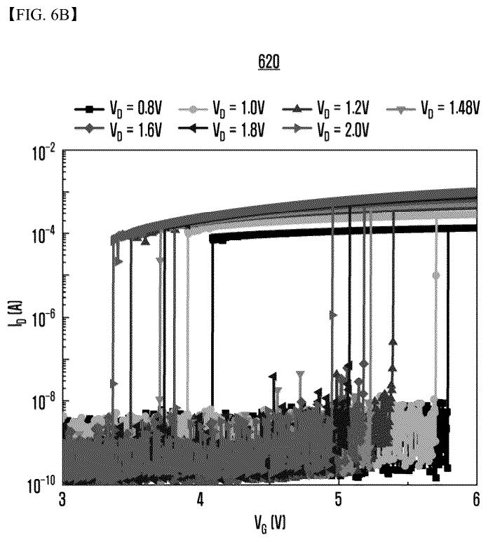

FIGS. 6A and 6B are embodiments of memory operation of the n-type bulk silicon memory device of the present disclosure.

FIGS. 6A and 6B are examples of operation due to a feedback loop phenomenon of a specific bulk silicon memory device through a semiconductor parameter analyzer, and accumulation and annihilation phenomena of electrons and holes due to the presence of potential wells may be confirmed, showing that the device may operate as a memory device without a capacitor.

The graph 610 of FIG. 6A shows a relationship between drain current (I_{D}) and drain voltage (V_{D}) according to changes in gate voltage (V_{G}).

FIG. 6A includes results of measuring changes in drain current (I_{D}) while increasing drain voltage (V_{D}) from 0V to 4V under conditions where gate voltage (V_{G}) changes from 3.0V to 5.5V. This graph shows that the n-type bulk silicon memory device 500 stably performs memory operation through a positive feedback mechanism.

In FIG. 6A, in a region where drain voltage (V_{D}) is low (0V to 1V), drain current (I_{D}) maintains a very low value, which is because the p-n junction structure of the p-well and the n-well provides electrical isolation to effectively block leakage current.

When gate voltage (V_{G}) is 3.0V, drain current (I_{D}) is maintained at approximately 10⁻⁹ A level, which indicates that the device is in an “OFF state.” However, as gate voltage (V_{G}) increases, drain current (I_{D}) begins to show exponential increase, which is because voltage applied to the gate forms an electric field to induce electrical connection between the p+ drain and the n+ source.

When gate voltage (V_{G}) becomes 5.0V or higher, drain current (I_{D}) rapidly increases to a value of 10⁻³ A or more, which indicates that the memory device has switched to an “ON state.” In this process, the positive feedback mechanism amplifies current flow through accumulation of electrons and holes and significantly improves switching speed and stability of the memory device. The triple-well layer induces current to flow along specific paths and blocks unnecessary current leakage. These results experimentally demonstrate that the n-type bulk silicon memory device may operate stably without a capacitor.

FIG. 6B is a graph 620 showing memory operation characteristics of the n-type bulk silicon memory device 500 of the present disclosure and shows a relationship between drain current (I_{D}) and gate voltage (V_{G}) according to changes in drain voltage (V_{D}).

FIG. 6B includes results of measuring changes in drain current (I_{D}) while increasing gate voltage (V_{G}) from 3.0V to 6.0V under conditions where drain voltage (V_{D}) changes from 0.8V to 2.0V.

In FIG. 6B, as gate voltage (V_{G}) increases, drain current (I_{D}) shows exponential increase, which is because an electric field induced by gate voltage amplifies current flow through a positive feedback mechanism.

When drain voltage (V_{D}) is 2.0V, if gate voltage (V_{G}) increases to 4.5V or higher, drain current (I_{D}) shows a value of 10⁻³ A or more, which indicates that the memory device has switched to an “ON state.” In this state, current flow between the p+ drain and the n+ source is stably maintained, and the device provides a wide current sensing margin. In addition, the p-n junction structure and the triple-well layer prevent electrical interference between devices and enable stable signal transmission.

FIGS. 6A and 6B each show that the n-type bulk silicon memory device operates stably in response to changes in gate voltage (V_{G}) and drain voltage (V_{D}).

Both graphs demonstrate that the n-type bulk silicon memory device may implement memory operation without a capacitor by utilizing a positive feedback mechanism, and this operation is maintained more stably by the p-n junction structure and the triple-well layer.

Consequently, by using the present disclosure, it is possible to implement a memory device composed of one transistor by utilizing a positive feedback mechanism without a capacitor in a conventional 1T-1C structure DRAM structure.

In addition, stable memory operation is possible by blocking leakage current flowing to the bulk silicon substrate, and integration density improvement and power consumption reduction are possible by being compatible with CMOS processes.

Furthermore, by utilizing a bulk silicon substrate and without complex processes such as epitaxy, the process is easy, and processing speed may be increased due to characteristics of a wide memory operation window and a wide current sensing margin.

According to an embodiment, leakage current may be blocked while omitting complex epitaxial processes on a bulk silicon substrate.

According to an embodiment, operation of a one-transistor memory device may be stably implemented without a capacitor based on a positive feedback mechanism.

According to an embodiment, interference between memory devices may be reduced and reliability may be improved by utilizing a p-n junction and a triple-well layer.

According to an embodiment, manufacturing costs may be reduced and economy may be enhanced by utilizing a bulk silicon substrate.

According to an embodiment, stable operating characteristics may be maintained even in high-temperature environments by improving thermal conductivity of the memory device.

As described above, although the embodiments have been described with reference to limited drawings, those skilled in the art will appreciate that various modifications and variations are possible from the above description. For example, appropriate results may be achieved even if the described techniques are performed in an order different from the described method, and/or components of the described system, structure, device, circuit, etc. are combined or combined in a form different from the described method, or are replaced or substituted by other components or equivalents.

Therefore, other implementations, other embodiments, and equivalents to the claims also fall within the scope of the claims described below.

What is claimed is:

1. An n-type bulk silicon memory device comprising:
a triple-well layer formed on a bulk silicon substrate, the triple-well layer comprising an n-well formed on the bulk silicon substrate, a p-well formed within the n-well, and an n-well formed again within the p-well;
a p+ drain formed within the n-well and an n+ source formed within the p-well;
an insulating layer covering the p-well, the n-well, the p+ drain, and the n+ source;
a metal wiring layer formed on the insulating layer and configured to transmit electrical signals; and
a passivation layer configured to protect the metal wiring layer.

2. The n-type bulk silicon memory device of claim 1, wherein the bulk silicon substrate comprises a p-type or n-type semiconductor substrate.

3. The n-type bulk silicon memory device of claim 1, wherein the metal wiring layer is formed in a multilayer structure of copper (Cu) and aluminum (Al) to reduce resistance loss of electrical signals.

4. The n-type bulk silicon memory device of claim 1, wherein the passivation layer is formed of silicon oxynitride (SiON) to enhance electrical insulation properties.

5. The n-type bulk silicon memory device of claim 1, wherein the insulating layer is formed to cover the bulk silicon substrate and the triple-well layer, and has a thickness between 5 nm and 10 nm.

6. The n-type bulk silicon memory device of claim 1, wherein the triple-well layer is formed between the n+ source and the p+ drain to provide electrical isolation between an active region and an inactive region of the bulk silicon substrate.

7. The n-type bulk silicon memory device of claim 1, wherein the triple-well layer comprising the n-well, the p-well, and the n-well formed again includes a p-n-p-n junction to eliminate leakage current paths.

8. The n-type bulk silicon memory device of claim 1, wherein the metal wiring layer is formed in a multilayer structure with an insulating layer inserted between each layer.

9. A method of manufacturing an n-type bulk silicon memory device, the method comprising:
forming a triple-well layer on a bulk silicon substrate, the triple-well layer comprising an n-well, a p-well, and an n-well formed again;
forming a p+ drain within the n-well and forming an n+ source within the p-well;
forming an insulating layer covering the triple-well layer;
forming a metal wiring layer on the insulating layer; and
forming a passivation layer to protect the metal wiring layer.

10. The method of claim 9, wherein forming the triple-well layer comprises injecting donor ions and acceptor ions into the bulk silicon substrate to generate the n-well, the p-well, and the n-well formed again.

11. The method of claim 9, wherein forming the insulating layer comprises applying a thermal oxidation process to a surface of the bulk silicon substrate to form a silicon oxide layer (SiO₂).

12. The method of claim 9, wherein forming the metal wiring layer comprises depositing a metal thin film comprising copper (Cu) or aluminum (Al), and forming wiring configured to transmit electrical signals through lithography and etching processes.

13. The method of claim 9, wherein the p+ drain is formed through acceptor ion implantation.

14. The method of claim 9, wherein the insulating layer is formed through a thermal oxidation process to prevent electrical interference that may occur on the bulk silicon substrate.

15. The method of claim 9, wherein the passivation layer is formed through a plasma deposition process.

16. The method of claim 9, wherein the insulating layer is formed by applying a Local Oxidation of Silicon (LOCOS) process to eliminate leakage current on a surface of the bulk silicon substrate.

17. The method of claim 9, wherein the triple-well layer is formed through a high-concentration ion implantation process to prevent electrical interference between the p-well and the n-well formed on the bulk silicon substrate.

18. An n-type bulk silicon memory device structure, wherein a triple-well having a p-n-p-n structure in which a p-well and a p+ region are isolated from each other through an n-well is formed in an active channel region of a bulk silicon substrate, thereby eliminating a leakage path through electrical isolation by p-n junction.

19. The n-type bulk silicon memory device structure of claim 18, wherein, for regions other than the active channel region of the bulk silicon substrate, a leakage path generated toward a substrate surface is eliminated through a Local Oxidation of Silicon (LOCOS) process.
